(19) United States
(12) Patent Application Publication
(10) Pub. No.: US 2005/0009337 A1
(43) Pub. Date: Jan. 13, 2005

(54) [METAL SILICIDE STRUCTURE AND METHOD OF FORMING THE SAME]

(76) Inventors: Hung-Wei Liu, Taichung (TW); Kuang-Chao Chen, Hsinchu (TW); Hsueh-Hao Shih, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/604,835

(22) Filed: Aug. 21, 2003

(30) Foreign Application Priority Data
Jul. 10, 2003 (TW) 92118825

(51) Int. Cl. H01L 21/44

(52) U.S. Cl. 438/682

(57) ABSTRACT

A method of forming a suicide layer is described. A silicon layer is provided. Ions are introduced in the silicon layer. A metal layer is formed on the silicon layer. An annealing process is performed so that the silicon layer reacts with the metal layer to form the metal silicide layer. Thereafter, the unreacted metal layer is removed. The uniformity of the grain size and the grain distribution of the metal silicide layer are improved by introducing the ions in the silicon layer before performing the annealing process, so that sheet resistance of the metal silicide layer is reduced.

### BACKGROUND OF INVENTION

1. Field of Invention

The present invention relates to a material and a method of forming the same. More particularly, the present invention relates to a metal silicide structure and a method of forming the same.

2. Description of Related Art

The metal oxide semiconductor (MOS) transistor, which usually serves as a switch, includes a gate and a source/drain. The conventional MOS transistor consists of the metal layer, silicon oxide layer and the silicon substrate. However, the adhesion between the metal layer and the oxide layer is poor, therefore it is desirable to replace the metal layer with the polysilicon layer. But, the use of the polysilicon layer causes other problems. For example, the polysilicon layer is not suitable for forming the gate, because the sheet resistance of the polysilicon layer is too high, even if the polysilicon layer is doped.

Currently, the polysilicon layer is replaced by the refractory metal silicide on top of the doped polysilicon layer, such a structure is termed a polycide. The metal silcide layer has high conductivity, so that polycide can be used for the gate conductive layer to perform the operation of the gate. The material of the metal silicide used in the semiconductor process comprises tungsten silicide (WSi₂) and titanium silicide (TiSi₂).

The polycide layer is usually formed by depositing a metal silicide layer such as a tungsten silicide layer or a titanium silicide layer on the polysilicon layer. Another method, such as salicidation process. The salicidation process includes forming a metal layer on the polysilicon layer, and then performing an annealing process to form a metal silicide layer. The metal silicide grains grow into larger grains in the annealing process, but the grain distribution is not uniform and the high temperature affects the stability of the metal silicide. Hence, the sheet resistance of the metal silicide layer formed by the salicidation process is usually very high. Consequently, the operation of the devices is adversely affected, and the problem of open circuit occurs thereby decreasing the process yield.

### SUMMARY OF INVENTION

This invention provides a method of forming a metal silicide layer to reduce the sheet resistance of the metal silicide layer.

This invention provides a method of fabricating a semiconductor device to reduce the sheet resistance of the gate and the source/drain.

The present invention provides a method of forming a metal silicide layer. A silicon layer is provided. Ions, for example, nitrogen ions or inert ions such as argon ions are introduced into the silicon layer to form a barrier layer in the silicon layer. A metal layer is formed on the silicon layer, and then an annealing process is performed so that the silicon layer reacts with the metal layer to form a metal silicide layer. Thereafter, the unreacted metal layer is removed.

The ions introducing process for forming a barrier layer, which is performed before forming the metal layer, makes the metal silicide under the barrier layer formed in the subsequent process having uniform grains size and uniform grain distribution. Therefore, the metal silcide formed by this invention has low sheet resistance, so that the contact reliability of the metal silcide is improved.

The present invention also provides a metal silicide structure, wherein the structure comprises a first metal silicide layer, a barrier layer and a second metal silicide layer. The barrier layer, which has ions therein, is between the first metal silicide layer and the second metal silicide layer. The ions comprise nitrogen ions or inert ions. The grain distribution of the first metal silicide layer is more uniform than that of the second metal silicide.

The metal silicide under the barrier layer formed in the subsequent process has uniform grain size and uniform grain distribution. Therefore, the metal silcide formed by this invention has low sheet resistance, so that the contact reliability of the metal silcide is improved.

The present invention also provides a method of fabricating a semiconductor device. A gate structure including a gate dielectric layer and a polysilicon layer is formed on a substrate. A source/drain is formed beside the gate structure. A spacer is formed on the side wall of the polysilicon gate structure. Ions, for example, nitrogen ions or inert ions such as argon ions are introduced into the polysilicon layer and the source/drain to form a barrier layer therein. A metal layer is formed on the substrate, and then an annealing process is performed so that the polysilicon layer and the source/drain react with the metal layer to form a metal silicide layer. Thereafter, the unreacted metal layer is removed.

The ions introducing process for forming a barrier, which is performed before forming the metal layer, makes the metal silicide under the barrier layer formed in the subsequent process having uniform metal silicide grain size and uniform grain distribution. Therefore, the sheet resistance of the gate and the source/drain are reduced.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A-1C are cross sectional views illustrating the process for forming a metal suicide layer according to one preferred embodiment of this invention.

FIGS. 2A-2E are cross sectional views illustrating the process for fabricating a metal oxide semiconductor transistor according to another preferred embodiment of this invention.

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like portions.

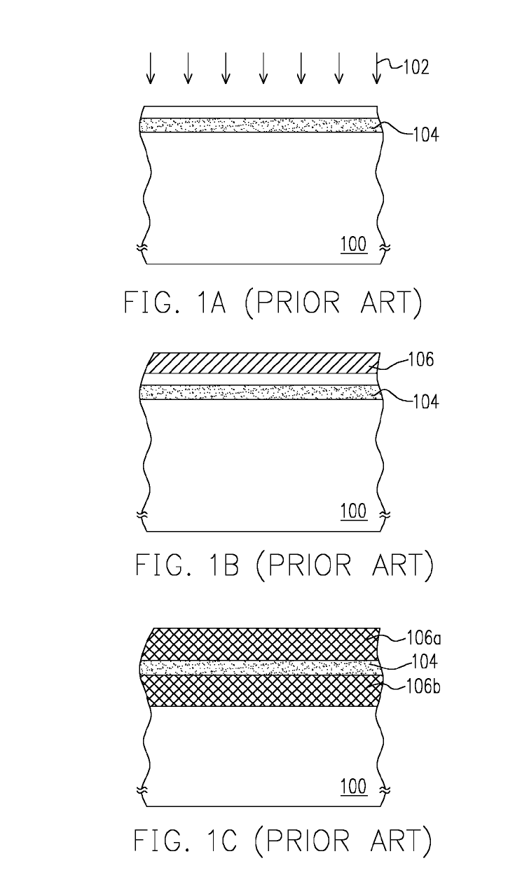

FIGS. 1A-1C are cross sectional views illustrating the process for forming a metal silicide layer according to one embodiment of this invention. Referring to FIG. 1A, a silicon layer 100 such as a silicon substrate or a polysilicon layer is provided.

Thereafter, an ion introducing process 102 is performed to introduce ions into the silicon layer 100 for forming a barrier layer 104 therein. According to the present invention, the ions that are introduced into the silicon layer 100 can bring about the grain size and distribution of the subsequently formed metal suicide uniform in the annealing process. The ions introducing process 102 is, for example, an ion implantation process. The introduced ions are, for example, nitrogen ions or inert ions such as argon ions.

Referring to FIG. 1B, a metal layer 106 is formed on the silicon layer 100, wherein the material of the metal layer 106 is selected from a group consisting of tungsten, molybdenum, cobalt, titanium and other refractory metal materials. The metal layer 106 is formed, for example, by using low pressure chemical vapor deposition (LPCVD).

Thereafter, referring to FIG. 1C, an annealing process is conducted, so that the silicon layer 100 reacts with the metal layer 106 to form metal silicide layers 106a and 106b. The temperature of the annealing process is, for example, 960° C. The duration of the annealing process 108 is, for example, 360 seconds. During the annealing process, the metal layer 106 and the silicon layer 100 adjacent to the metal layer 106 are melted under high temperature condition, and the metal grains and the silicon grains are rearranged to form the metal silicide layers 106a and 106b. The metal silicide layers 106a and 106b, for example, comprise a tungsten silicide layer, a molybdenum suicide layer, a cobalt silicide layer, a titanium silicide layer and other refractory metal silicide layers. Thereafter, the unreacted metal layer 106 is removed.

As shown in FIG. 1B, the silicon layer 100 is introduced with ions to form the barrier 104 therein, so that the barrier layer 104 separate the silicon layer 100 into two portions. In other words, after performing the annealing process, the metal silicide layer includes two portions 214a and 214b separated by the barrier layer 104. The sheet resistance of the upper metal silicide layer 106a over the barrier layer 104 is similar to the metal silicide layer of the prior art. However, the lower metal silicide layer 106b under the barrier layer 104 has uniform grain size and uniform grain distribution, so that the sheet resistance of the lower metal silicide layer 106b is lower than the metal silicide layer of the prior art.

The metal silicide structure of the invention comprises a first metal silicide layer 106b, a barrier layer 104 and a second metal silicide layer 106a. The barrier layer 104 is located between the first metal silicide layer 106b and the second metal silicide layer 106a. The barrier layer 104 is a silicon layer with ions, for example, nitrogen ions or inert ions such as argon ions. The first metal silicide layer 106b and the second metal suicide layer 106a, for example, comprise a tungsten silicide layer, a molybdenum silicide layer, a cobalt silicide layer or a titanium silicide layer. In addition, the grain size and the grain distribution of the first metal silicide layer 106b are uniform compared to those of the second metal silicide layer 106a.

The following process of fabricating a metal oxide semiconductor (MOS) transistor is illustrated according to a preferred embodiment of the present invention, however, this is used as an example without restricting the scope of the invention. It will be apparent to those skilled in the art that the metal slicide structure of the present invention can be applied to other integrated circuit process without departing from the scope or spirit of the invention.

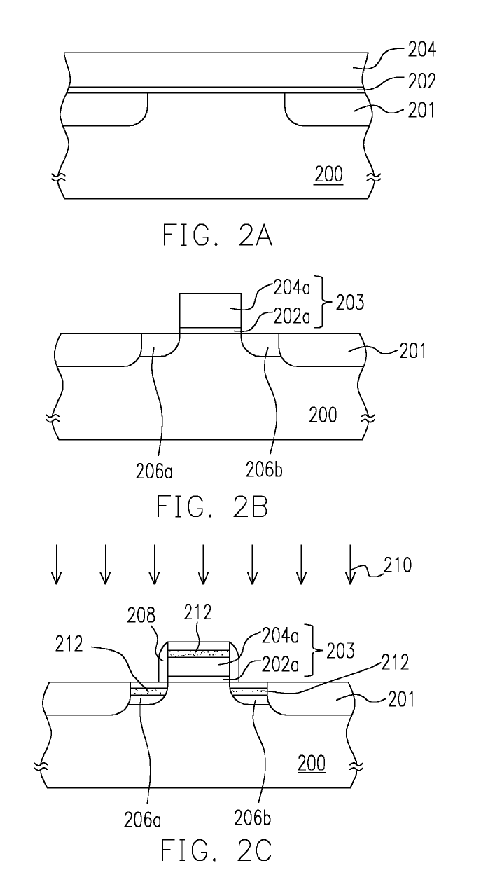

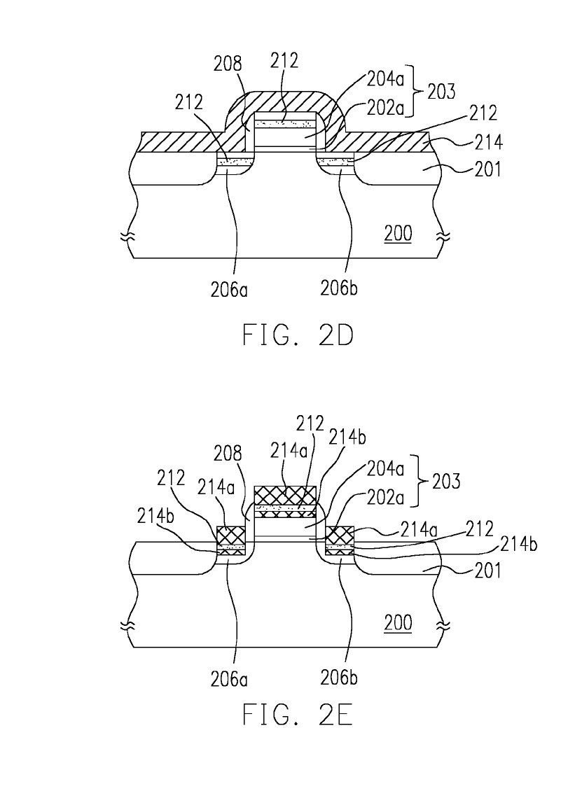

FIGS. 2A-2E are cross sectional views illustrating the process for fabricating a metal oxide semiconductor transistor according to the second preferred embodiment of this invention. Referring to FIG. 2A, a substrate 200, such as a silicon substrate, having an isolation region 201 therein is provided. A gate dielectric layer 202 is formed on the substrate 200, and a gate conductive layer 204 including a silicon layer, such as a polysilicon layer or a doped polysilicon layer is formed on the gate dielectric layer 202. The gate conductive layer 204 is formed by, for example, chemical vapor deposition.

Referring to FIG. 2B, the gate conductive layer 204 and the gate dielectric layer 202 are patterned for forming a patterned gate conductive layer 204a and a patterned gate dielectric layer 202 to construct a gate structure 203. The gate conductive layer 204 and the gate dielectric layer 202 are patterned by, for example, forming a patterned photoresist layer on the gate conductive layer 204, and then performing an anisotropic etching process using the patterned photoresist layer as mask to form the patterned gate conductive layer 204a and the patterned gate dielectric layer 202a.

Thereafter, a source 206a and a drain 206b are formed in the substrate 200 beside the gate structure 203. The source 206a and the drain 206b are formed by, for example, conducting an ion implantation process to introduce ions into the substrate 200 using the gate structure 203 as a mask. The ion types of the ion implantation process including N-type and P-type dependent on the type of metal oxide semiconductor transistor. The n type ions comprise arsenic ions, and the P-type ions comprise boron fluoride ions.

When the ion type of the source/drain are N-type, the source 206a and the drain 206b are a lightly doped source/drain. An additional ion implantation process is performed after forming the spacer to introduce ions into substrate for forming heavily doped source/drain (not shown).

Referring to FIG. 2C, a spacer 208 is formed on the side wall of the gate structure 203, for example, by forming a dielectric layer (not shown in FIG.) on the substrate 200, followed by performing an etching back process, such as an anisotropic etching process. The dielectric layer is formed, for example, by low-pressure chemical vapor deposition using reacting gases depending on the material of the dielectric layer.

Thereafter, an ion introducing process 210 is perform to introduce ions into the gate conductive layer 204a, the source 206a and the drain 206b for forming a barrier layer 212 in the gate conductive layer 204a, the source 206a and the drain 206b. The ions introducing process 210 for example, is, an ion implantation process. The introduced ions, for example, comprise nitrogen ions or inert ions such as argon ions. When the introduced ions are argon ions, the implanted dosage is about 2×10¹⁵/cm² to 6×10¹⁵/cm².

Continuing to FIG. 2D, a metal layer 214 is deposited on the substrate 200, wherein the material of the metal layer 214 is selected from a group consisting of tungsten, molybdenum, cobalt, titanium and other refractory metal materials. The metal layer 214, for example, is formed by low pressure chemical vapor deposition.

Referring to FIG. 2E, an annealing process is conducted, so that the gate conductive layer 204a, the source 206a and the drain 206b react with the metal layer 214 to form a metal silicide layers 214a and 214b. The temperature of the annealing process is, for example, 960° C. The duration of the annealing process 108 is, for example, 360 seconds. During performing the annealing process, the metal layer 106 and the substrate 200 adjacent to the metal layer 214 are melted under high temperature condition, and the metal grains and the silicon grains are rearranged to form the metal silicide layers 214a and 214b. The metal silicide layers 214a and 214b, for example, comprises a tungsten silicide layer, a molybdenum silicide layer, a cobalt silicide layer, a titanium silicide layer and other refractory metal silicide layers. Thereafter, the unreacted metal layer 214, which is not reactive with the gate conductive layer 204a, the source 206a and the drain 206b, is removed.

As shown in FIG. 2C, since the gate conductive layer 204a, the source 206a and the drain 206b are introduced with ions to form the barrier layer 212, so that the barrier layer 212 separate gate conductive layer 204a, the source 206a and the drain 206b into two portions, respectively. In other words, after performing the annealing process, the metal silicide layer includes two portions 214a and 214b separated by the barrier layer 212. The sheet resistance of the upper metal silicide layer 214a over the barrier layer 212 is similar to the metal silicide layer of the prior art. However, the lower metal silicide layer 214b under the barrier layer 212 has uniform grain size and uniform grain distribution, so that the sheet resistance of the lower metal silicide layer 214b is lower than the metal silicide layer of the prior art. Since the sheet resistance of the metal silicide layer is reduced, the sheet resistance of the gate and the source/drain are reduced. Thus, the performance of the devices is improved.

The following examples exemplify the present invention describing the scheme of reducing the sheet resistance of the metal silicide. In the examples, the metal silicide formed in the salicidation process relates to the titanium silicide. The titanium silcide layer is formed by forming a titanium layer on the silicon layer, performing an annealing process and removing the unreacted metal layer. The annealing process is performed at the temperature of 960° C. for the duration of 360 seconds. The sheet resistance (ohm/square) of the titanium silicide layer is measured during the annealing process for each interval of 60 seconds as shown in table 1.

The argon ion implantation process before conducting the annealing process is not performed in example 1, but that is performed in examples 2 and 3. The implanted dosage in the example 2 is 2×10¹⁵/cm², and in the example 3 is 6×10¹⁵/cm².

| | Sheet resistance (ohm/square) | | |
|---|---|---|---|
| Time (sec) | Example 1 | Example 2 | Example 3 |
| 0 | 5.905 | 3.828 | 3.066 |
| 60 | 15.675 | 4.478 | 3.391 |
| 120 | 70.486 | 5.502 | 4.436 |
| 180 | 202.090 | 7.202 | 6.443 |
| 240 | — | 10.694 | 10.758 |
| 300 | 154.840 | 17.636 | 19.755 |
| 360 | 155.510 | 28.717 | 33.530 |

From table 1, the sheet resistance of the titanium suicide in examples 2 and 3 is lower than that in example 1. Hence, it is evident that the sheet resistance of the titanium silicide of the present invention is really reduced. In other words, the thermal stability of the metal salicide is improved.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

1. A method for forming a metal silicide layer, comprising:
provding a silicon layer;
introducing ions in the silicon layer to form a barrier layer in the silicon layer;
forming a metal layer on the silicon layer;
performing an annealing process so that the silicon layer reacts with the metal layer to form the metal silicide layer; and
removing the unreacted metal layer.

2. The method of claim 1, wherein the ions comprises inert ions or nitrogen ions.

3. The method of claim 2, wherein the inert ions includes argon ions.

4. The method of claim 1, wherein a material of the metal is selected from a group consisting of tungsten, molybdenum, cobalt and titanium.

5. The method of claim 1, wherein the step of introducing ions in the silicon layer is performed by an ion implantation process.

6. A method of forming semiconductor device, comprising:
forming a gate structure on a substrate, wherein the gate structure comprised a silicon layer;
forming a source/drain region beside the gate structure;
forming a spacer on the side wall on the gate structure;
introducing ions into the silicon layer and the source/drain to form a barrier layer in the silicon layer and the source/drain;
forming a metal on the substrate;
performing an annealing process so that the silicon layer and the source/drain react with the metal layer to form a metal silicide layer; and
removing the unreacted metal layer.

7. The method of claim 1, wherein the ions comprises inert ions or nitrogen ions.

8. The method of claim 7, wherein the inert ions includes argon ions.

9. The method of claim 8, wherein a material of the metal is selected from a group consisting of tungsten, molybdenum, cobalt and titanium.

10. The method of claim 7, wherein the step of introducing ions in the silicon layer is performed by an ion implantation process.

11. A metal silicide structure, comprising:
a first metal silicide layer;
a second metal silicide layer, wherein the grain distribution of the first metal silicide layer is more uniform than that of the second metal silicide; and
a barrier layer between the first metal silicide layer and the second metal silicide layer, wherein the barrier layer comprises ions.

12. The structure of claim 11, wherein the ions comprises inert ions or nitrogen ions.

13. The structure of claim 12, wherein the inert ions includes argon ions.

14. The structure of claim 11, wherein a material of the metal is selected from a group consisting of tungsten, molybdenum, cobalt and titanium.
